(19) United States
(12) Patent Application Publication
(10) Pub. No.: US 2023/0047794 A1
(43) Pub. Date: Feb. 16, 2023

(54) Multi-trench Super-Junction IGBT Device

(71) Applicant: Shanghai Supersemiconductor Technology Co., Ltd., Shanghai (CN)

(72) Inventors: Yuzhou WU, SHANGHAI (CN); Fei LI, SHANGHAI (CN); Xin LI, SHANGHAI (CN); Tiechuan LIU, SHANGHAI (CN); Jiuying YU, SHANGHAI (CN)

(73) Assignee: Shanghai Supersemiconductor Technology Co., Ltd., SHANGHAI (CN)

(21) Appl. No.: 17/683,346

(22) Filed: Feb. 28, 2022

(30) Foreign Application Priority Data
Aug. 10, 2021 (CN) 202110911954.8

(51) Int. Cl. H01L 29/06; H01L 23/552; H01L 29/10; H01L 29/739; H01L 29/66

(52) U.S. Cl. CPC H01L 29/0607; H01L 23/552; H01L 29/1095; H01L 29/0696; H01L 29/7397; H01L 29/66348; H01L 29/1608

(57) ABSTRACT

A multi-trench super junction IGBT device includes a metallization collector, a P-type substrate, a first N-type epitaxial layer located above the P-type substrate and a second N-type epitaxial layer located above the first N-type epitaxial layer. The second N-type epitaxial layer includes at least a first dummy MOS cell unit and a MOS cell unit, wherein the first dummy MOS cell unit includes a trench formed by reactive ion etching, a thermally grown gate oxide layer provided inside the trench and deposited heavily doped polysilicon located in the gate oxide layer.

The present application claims the priority of Chinese Patent Application No. 202110911954.8, filed on Aug. 10, 2021, the entire disclosure of which is hereby incorporated by reference.

### TECHNICAL FIELD

The present disclosure is in the technical field of power semiconductor devices, and particularly relates to a multi-trench super-junction IGBT device.

### BACKGROUND

A conventional super-junction insulated gate bipolar transistor (IGBT) device structure in the prior art is as shown in FIG. 1, comprising a metallization collector 1, a P-type substrate 2, a first N-type epitaxial layer 3 located above the P-type substrate 2, a P-column 4 formed in the first N-type epitaxial layer by a deep trench etching and backfilling process, and a second N-type epitaxial layer 5 located above the first N-type epitaxial layer 3 and the P-column 4, wherein there is only one MOS cell 50 in the second N-type epitaxial layer 5; the MOS cell 50 comprising a trench 6 formed by etching, a thermally grown gate oxide layer 7, a deposited heavily doped polysilicon 8, a P-type body region 9 formed by a self-alignment process, wherein the P-type body region 9 is provided with a partially mutually independent N+ source region 10, a deposited BPSG 11, and an emitter 12 metallizing on an upper surface.

The super-junction IGBT device is a new type of power semiconductor device based on the traditional IGBT device structure, which is added with alternate PN columns on the epitaxial layer. The formation of PN columns has similar effect to the super-junction MOS devices in the optimization of the parameters such as voltage blocking and forward conduction voltage drop of the devices. The introduction of PN columns leads to the result that, when the super-junction IGBT device operates in forward blocking mode, besides the longitudinal electric field of the Pbody-N-Epi junction, the mutual depletion of the PN columns generates a transverse electric field, which modulates the triangular electric field distribution of the traditional IGBT device to approximate the rectangular distribution, and greatly improves the voltage blocking capability of the super-junction IGBT device. On the premise of ensuring a certain breakdown voltage of the device, the concentration of N-Epi layer can be significantly increased, so as to significantly reduce the forward conduction voltage drop and help the super-junction IGBT device to significantly reduce the conduction loss in application. Under the same current specification, the area of super-junction IGBT device can be greatly reduced, and the chip cost can be reduced.

The formation of super junction structure in super-junction IGBT device follows the process of super junction MOS, and there are two main manufacturing methods. One is forming a super-junction structure by multiple epitaxy and implantation, while the other is done by deep trench etching and backfilling. Both of these two manufacturing methods are currently in common use, and are divided into different generations of products according to the width (pitch) of PN columns. For example, the pitch of Infineon C3 process is 16 μm, the pitch of C6, P6 process is 12 μm, and the pitch of C7, P7 process is 5.5 μm, with only one MOS cell structure in each pitch.

The superior electrical performance of super junction IGBT devices results in smaller chip area and higher current density. Smaller chip area leads to smaller gate input capacitance. When super junction IGBT device is used to replace the traditional IGBT device, the strong driving current of the driving chip will lead to current oscillation when the super-junction IGBT device is turned on, resulting in EMI problems and even device burn-out. Therefore, the super-junction IGBT device can not directly replace the traditional IGBT device in the application, need to adjust the peripheral circuit or replace the drive chip with smaller driving current, but indirectly increase the system cost and complexity of using the solution. At the same time, improving the current density of IGBT devices is also a key direction of IGBT technology development.

### SUMMARY OF THE DISCLOSURE

In view of this, the technical problem to be solved by the present disclosure is to provide a multi-trench super-junction IGBT device, which can adjust the gate input capacitance of the super-junction IGBT device without changing the process complexity of the device and without affecting the breakdown voltage of the device, prevent the current oscillation when the device is turned on, and enhance the EMI resistance of the device, and can directly replace the traditional IGBT device in application. It also has the characteristics of regulating saturated output current density, forward conduction voltage drop and short circuit capacity.

The technical solution of the present disclosure is multi-trench super-junction IGBT device, comprising a metallization collector, a P-type substrate, a first N-type epitaxial layer located above the P-type substrate and a second N-type epitaxial layer located above the first N-type epitaxial layer, a P-column being formed in the first N-type epitaxial layer through multiple epitaxy and implantation or deep trench etching and backfilling processes, wherein the second N-type epitaxial layer at least comprises one first dummy MOS cell unit and one MOS cell unit, the first dummy MOS cell unit and the MOS cell unit having the same structure, and the first dummy MOS cell unit comprising a trench formed by reactive ion etching, a thermally grown gate oxide layer and a deposited heavily doped polysilicon located in the gate oxide layer which are provided inside the trench, a P-type body region formed by a self-alignment process, a deposited BPSG located above the P-type body region, and an emitter metallized on an upper surface located above the BPSG,

the second N-type epitaxial layer further comprising a second dummy MOS cell unit, the second dummy MOS cell unit, the first dummy MOS cell unit, and the MOS cell unit having the same structure, and the P-type body region of the second dummy MOS cell unit not having a potential connected to the emitter, and

a plurality of mutually independent source regions being provided in the P-type body region of the MOS cell unit.

Preferably, a number and proportion of the first dummy MOS cell unit, the second dummy MOS cell unit, and the MOS cell unit in the second N-type epitaxial layer are adjusted according to application requirements, wherein there is at least one MOS cell unit, and they may all be MOS cell units.

Preferably, resistivity of the second N-type epitaxial layer is larger than that of the first N-type epitaxial layer, and the resistivity of the second N-type epitaxial layer is in a range of 4-40 Ω·cm.

Preferably, a thickness of the second N-type epitaxial layer is in a range of 4-40 μm.

Preferably, the P-column is formed by deep trench etching and silicon backfilling process or multiple epitaxy and ion implantation and formed by high-temperature annealing

Preferably, the P-column is not in contact with the P-type body region and the trench.

Preferably, an upper layer of the metallization collector is epitaxially formed with a field stop layer having a lower resistivity than the resistivity of the first N-type epitaxial layer, the field stop layer having a thickness in a range of 10-40 μm.

Preferably, the solution of the present invention is applicable to P-channel multi-trench super junction IGBT devices.

Preferably, bulk silicon, silicon carbide, gallium arsenide, indium phosphide or silicon germanium can be adopted as a semiconductor material in the IGBT device.

An advantageous effect of the present disclosure is that a multi-trench super-junction IGBT device can adjust the gate input capacitance of the super-junction IGBT device by adjusting the number of the first dummy MOS cell unit, the MOS cell unit and the second dummy MOS cell unit in a top structure of the device, and at the same time has the advantages of adjusting the saturated output current density, forward conduction voltage drop and short circuit capacity of the device. Adding the first dummy MOS cell unit can increase the gate input capacitance, prevent the current oscillation when the device is turned on, and improve the EMI resistance of the device. Adding the third dummy MOS cell unit can form an electron accumulation region under the P-type body region when forward conduction, modulate the carrier concentration distribution inside the device to be closer to the PIN diode, form a carrier injection enhancement effect, reduce the forward conduction voltage drop of the device and reduce the device conduction loss. According to the simulation data, adding the first dummy MOS cell unit can increase the gate input capacitance of the super-junction IGBT device by multiple. Adding two second dummy MOS cell units can reduce the forward conduction voltage drop by no less than 10%. Furthermore, the adding of the first dummy MOS cell unit and the second dummy MOS cell unit does not affect the breakdown voltage and short-circuit characteristics of the device. The MOS cell unit provides a base current of a parasitic PNP transistor to the super junction IGBT device, and adding the MOS cell unit can increase the electron-hole density of the first N-type epitaxial layer, thereby increasing the saturated output current density of the device, while reducing the forward conduction voltage drop and reducing the conduction loss.

### BRIEF DESCRIPTION OF THE DRAWINGS

FIG. 1 is a schematic structural diagram of a conventional super-junction IGBT device embodiment of the prior art;

FIG. 2 is a schematic structural diagram of a multi-trench super-junction IGBT device according to a first embodiment of the present disclosure;

FIG. 3 is a schematic structural diagram of a multi-trench super-junction IGBT device according to a second embodiment of the present disclosure;

FIG. 4 is a schematic structural diagram of a multi-trench super-junction IGBT device according to a third embodiment of the present disclosure;

FIG. 5 is a schematic structural diagram of a multi-trench super-junction IGBT device according to a fourth embodiment of the present disclosure; and

FIG. 6-1 is an epitaxial wafer adopted by a Wafer start, comprising a high-resistance P-type substrate and a first N-type epitaxial layer.

FIG. 6-2 is a super-junction structure for forming a super-junction IGBT device by forming a P-column using a deep trench reactive ion etching and a silicon backfilling process.

FIG. 6-3 shows that the second N-type epitaxial layer is formed by high-temperature epitaxy, and it is critical that the resistivity of the second N-type epitaxial layer is higher than that of the first N-type epitaxial layer so as to avoid walk out phenomenon during the test.

FIG. 6-4 shows the formation of a trench by reactive ion etching using Hard mask and carrier storage layer implantation.

FIG. 6-5 illustrates a dry oxidation method for thermally growing a gate oxide layer.

FIG. 6-6 illustrates the deposition of in-situ doped polysilicon and etching to form a gate.

FIG. 6-7 illustrates the formation of the P-type body region by self-alignment using ion implantation and a high-temperature drive in.

FIG. 6-8 illustrates the formation of the emitter region by photolithograph and implantation, the implanted region of the emitter region distinguishing a dummy MOS cell from a MOS cell.

FIG. 6-9 shows depositing BPSG, reflowing at a high temperature, performing contact photolithography and etching, and etching silicon with a thickness of 3000-5000 A, the opening or not of the contact distinguishing dummy cells, and then depositing a metal layer to form an emitter.

### DETAILED DESCRIPTION OF THE PREFERRED EMBODIMENTS

In order that the objects, technical solutions and advantages of the disclosure will become more apparent, a complete description of the technical solution of the present disclosure will be rendered in a detailed manner in combination with the drawings in the embodiments of the present disclosure. It is to be understood that the described embodiments are a part of, and not all embodiments of, the present disclosure, and that all other embodiments, obtained by a person skilled in the art without any inventive effort on the basis of the embodiments of the present disclosure, fall within the scope of protection of the present disclosure. The principle and features of the present disclosure will be illustrated by the following description taken in conjunction with the accompanying drawings, and the examples provided are only for explanation of the present disclosure, not limiting the scope of the present disclosure.

It will be understood that terms such as “having”, “including”, and “comprising”, as used herein, do not exclude the presence or addition of one or more other elements or groups thereof At the same time, in order to clearly illustrate the specific implementations of the present disclosure, the schematic drawings listed in the figures of the description enlarge the thickness of the layers and regions described in the present disclosure, and the sizes of the graphs listed do not represent actual dimensions. The drawings are schematic and should not limit the scope of the disclosure. The examples listed in the description should not be limited to the specific shapes of the regions shown in the drawings of the description, but include the resulting shapes such as the deviations caused by the preparation, etc.

As shown in FIG. 2, a multi-trench super junction IGBT device provided by a first embodiment of the present disclosure comprises a metallization collector 1, a P-type substrate 2, a first N-type epitaxial layer 3 located above the P-type substrate 2 and a second N-type epitaxial layer 5 located above the first N-type epitaxial layer 3, a P-column 4 being formed in the first N-type epitaxial layer 3 by multiple epitaxy and implantation or deep trench etching and backfilling processes, wherein the second N-type epitaxial layer 5 at least comprises one first dummy MOS cell unit 51 and one MOS cell unit 50, the first dummy MOS cell unit (51) and the MOS cell unit (50) having the same structure, and the first dummy MOS cell unit (51) comprising a trench (6) formed by reactive ion etching, a thermally grown gate oxide layer (7) and a deposited heavily doped polysilicon (8) located in the gate oxide layer (7) which are provided inside the trench (6), a P-type body region (9) formed by a self-alignment process, a deposited BPSG (11) located above the P-type body region (9) and an emitter (12) metallized on an upper surface located above the BPSG (11).

The second N-type epitaxial layer 5 may further comprise a second dummy MOS cell unit 52, wherein the second dummy MOS cell unit 52, the first dummy MOS cell unit 51 and the MOS cell unit 50 have the same structure, and the P-type body region 9 of the second dummy MOS cell unit 52 is not connected to a potential of the emitter 12.

A plurality of mutually independent source regions 10 are provided in the P-type body region 9 of the MOS cell unit 50.

Further, a number and a proportion of the second dummy MOS cell unit 52, the first dummy MOS cell unit 51 and the MOS cell unit 50 are adjusted in the second N-type epitaxial layer 5 according to application requirements, wherein there is at least one MOS cell unit 50, and they may all be MOS cell unit 50.

Further, resistivity of the second N-type epitaxial layer 5 is larger than that of the first N-type epitaxial layer 3, and the resistivity of the second N-type epitaxial layer 5 is in a range of 4-40 Ω·cm.

Further, a thickness of the second N-type epitaxial layer 5 is in a range of 4-40 μm.

Further, the P-column 4 is formed by deep trench etching and silicon backfilling process or multiple epitaxy and ion implantation and formed by high-temperature annealing

Further, the P-column 4 is not in contact with the P-type body region 9 and the trench 6.

Further, an upper layer of the metallization collector 1 is epitaxially formed with a field stop layer having a lower resistivity than the resistivity of the first N-type epitaxial layer (3), the field stop layer having a thickness in a range of 10-40 μm.

Further, the solution of the present invention is applicable to P-channel multi-trench super junction IGBT devices.

Further, bulk silicon, silicon carbide, gallium arsenide, indium phosphide or silicon germanium can be adopted as a semiconductor material in the IGBT device.

An advantage of the present disclosure is that the number of dummy MOS cells 51 and MOS cells 50 is increased, without being limited by the process pitch used by the device, and the super junction voltage blocking part of the super-junction IGBT device is separated from the top MOS part, and the two can be independently designed without being affected.

The second advantage of the present disclosure is that adding the first dummy MOS cell unit 51 does not change the main process flow of the super-junction IGBT device, and the solution has a strong operability.

The third advantage of the present disclosure is that the number of the first dummy MOS cell unit 51 can be flexibly increased according to application requirements, and the solution can monotonically increase the gate input capacitance of the super-junction IGBT device, thereby avoiding the problem of current oscillation when the device is turned on and EMI problem of the super-junction IGBT device. At the same time the breakdown voltage and short circuit capability of the device is not degraded. In addition to adding dummy MOS cells, MOS cell unit 50 can also be added, which can significantly improve the saturated output current density of the device, improve the conduction modulation state effect and reduce the forward conduction voltage drop of the device.

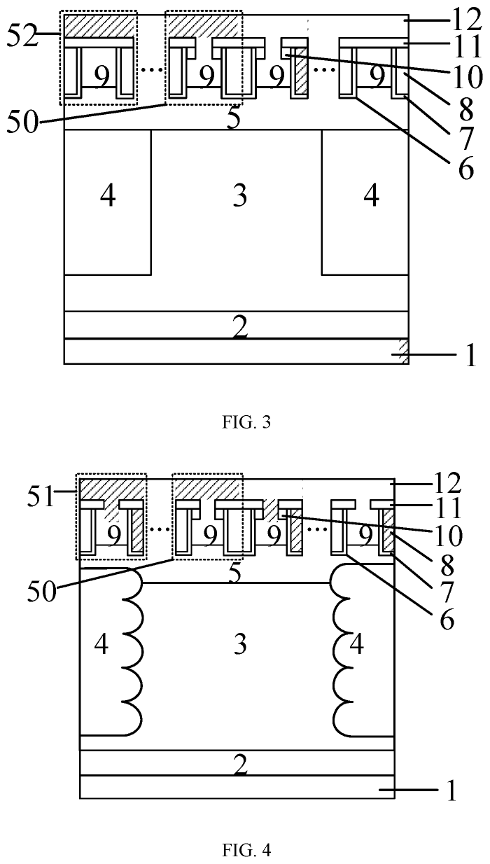

FIG. 3 is a structural schematic diagram of a multi-trench super-junction IGBT device of the present disclosure, wherein an emitter contact is not opened in a second dummy MOS cell unit 52, so that a potential of the P-type body region 9 is floating, which is advantageous for forming an electron accumulation layer below the P-type body region 9 when the device is conducted forward, and reducing the forward conduction voltage drop.

FIG. 4 is a schematic structural diagram of a multi-trench super-junction IGBT device of the present disclosure, corresponding to embodiment 1, wherein the super-junction part can be formed by multi-layer epitaxy and multiple ion implantation, the principle being the same as that of embodiment 1 of FIG. 2.

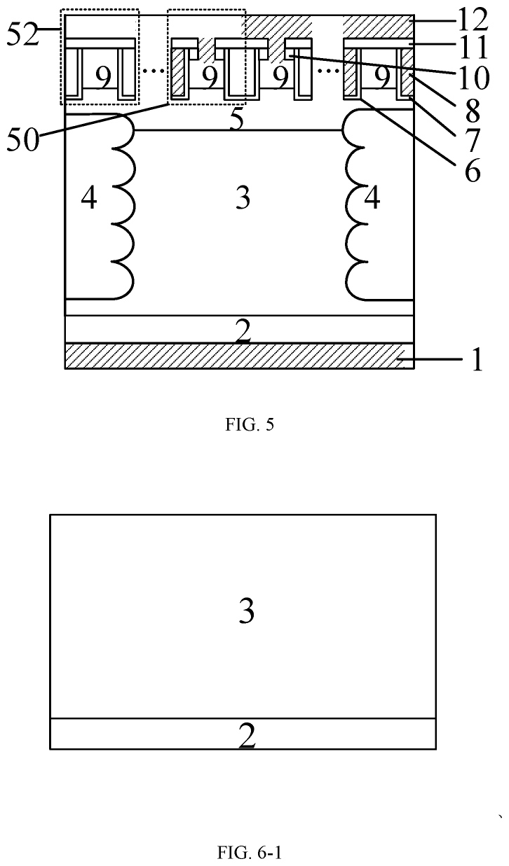

FIG. 5 is a schematic structural diagram of a multi-trench super-junction IGBT device of the present disclosure, corresponding to embodiment 2, wherein the super-junction part can be formed by multi-layer epitaxy and multiple ion implantation, the principle being the same as that of embodiment 2 of FIG. 3.

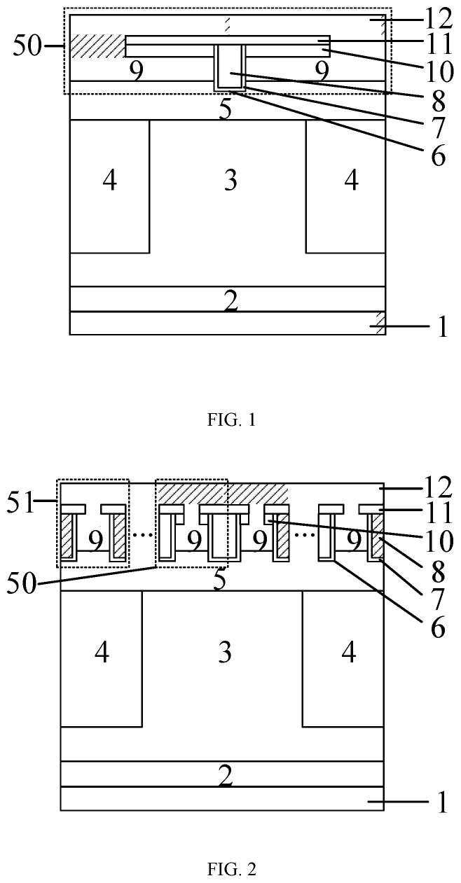

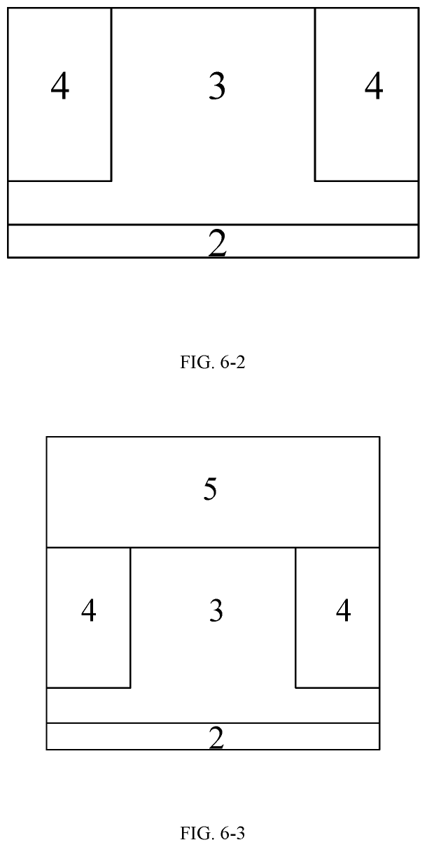

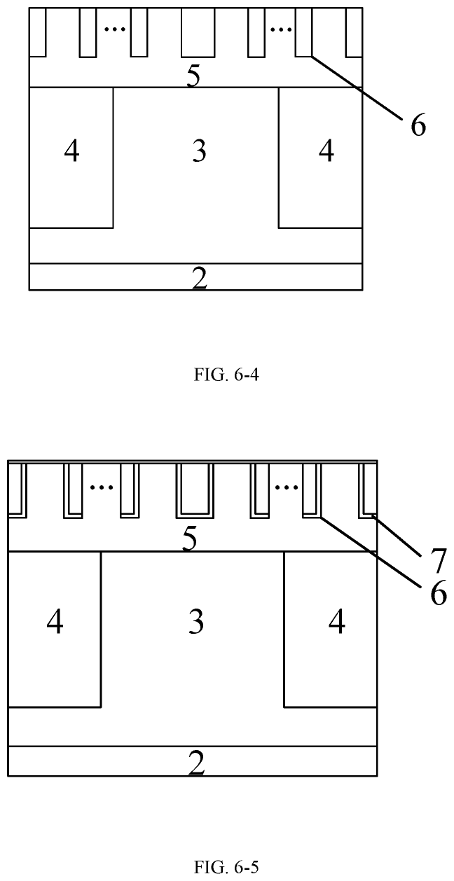

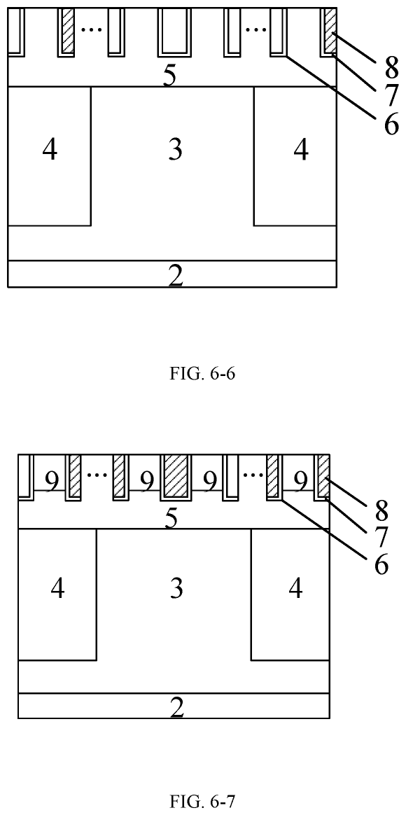

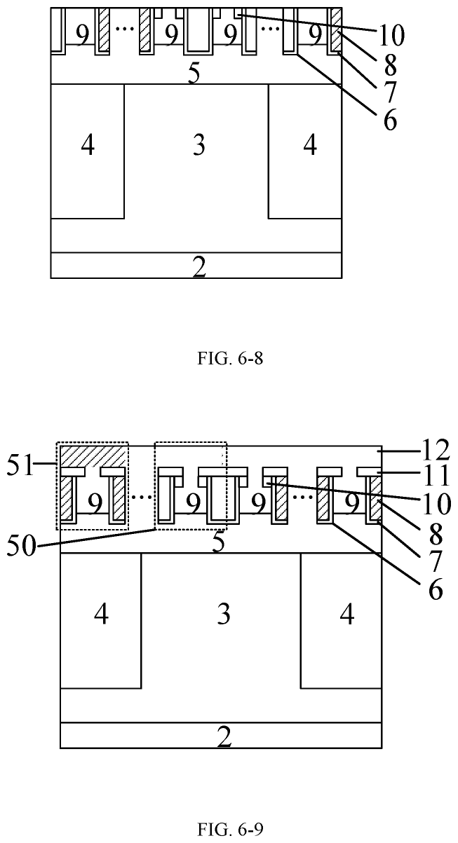

FIGS. 6-1 to 6-9 show a manufacturing flow chart of key steps of the first embodiment of the present disclosure. FIG. 6-1 is an epitaxial wafer adopted by a Wafer start, comprising a high-resistance P-type substrate 2 and a first N-type epitaxial layer 3. FIG. 6-2 is a super-junction structure for forming a super-junction IGBT device by forming a P-column 3 using a deep trench reactive ion etching and a silicon backfilling process. FIG. 6-3 shows that the second N-type epitaxial layer 5 is formed by high-temperature epitaxy, and it is critical that the resistivity of the second N-type epitaxial layer is higher than that of the first N-type epitaxial layer so as to avoid walk out phenomenon during the test. FIG. 6-4 shows the formation of a trench 6 by reactive ion etching using Hard mask and carrier storage layer implantation. FIG. 6-5 illustrates a dry oxidation method for thermally growing a gate oxide layer 7. FIG. 6-6 illustrates the deposition of in-situ doped polysilicon and etching to form a gate 8. FIG. 6-7 illustrates the formation of the P-type body region 9 by self-alignment using ion implantation and a high-temperature drive in. FIG. 6-8 illustrates the formation of the emitter region 10 by photolithograph and implantation, the implanted region of the emitter region distinguishing a dummy MOS cell 51 from a MOS cell 50. FIG. 6-9 shows depositing BPSG 11, reflowing at a high temperature, performing contact photolithography and etching, and etching silicon with a thickness of 3000-5000 A, the opening or not of the contact distinguishing dummy cells 51 and 52, and then depositing a metal layer to form an emitter 12. After the wafer is turned over and the device is thinned, P-type ions are implanted to form an ohmic contact, and a Ti/NiV/Ag metal layer is deposited to form a collector 1, finally forming the first embodiment of the present disclosure as shown in FIG. 2.

FIGS. 6-1 to 6-9 illustrate a manufacturing flow of a key step of an N-channel super-junction IGBT device, and the solution of the present disclosure is also applicable to a P-channel super-junction IGBT devices. Bulk silicon, silicon carbide, gallium arsenide, indium phosphide or silicon germanium can be adopted for a semiconductor material.

1. A multi-trench super-junction IGBT device, comprising a metallization collector (1), a P-type substrate (2), a first N-type epitaxial layer (3) located above the P-type substrate (2) and a second N-type epitaxial layer (5) located above the first N-type epitaxial layer (3), a P-column (4) being formed in the first N-type epitaxial layer (3) through multiple epitaxial and implantation or deep trench etching and backfilling processes, wherein the second N-type epitaxial layer (5) at least comprises one first dummy MOS cell unit (51) and one MOS cell unit (50), the first dummy MOS cell unit (51) and the MOS cell unit (50) having the same structure, and the first dummy MOS cell unit (51) comprising a trench (6) formed by reactive ion etching, a thermally grown gate oxide layer (7) and a deposited heavily doped polysilicon (8) located in the gate oxide layer (7) which are provided inside the trench (6), a P-type body region (9) formed by a self-alignment process, a deposited BPSG (11) located above the P-type body region (9), and an emitter (12) metallized on an upper surface located above the BPSG (11),
the second N-type epitaxial layer (5) further comprising a second dummy MOS cell unit (52), the second dummy MOS cell unit (52), the first dummy MOS cell unit (51), and the MOS cell unit (50) having the same structure, and the P-type body region (9) of the second dummy MOS cell unit (52) not having a potential connected to the emitter (12), and
a plurality of mutually independent source regions (10) being provided in the P-type body region (9) of the MOS cell unit (50).

2. The multi-trench super-junction IGBT device according to claim 1, characterized in that a number and proportion of the first dummy MOS cell unit (51), the second dummy MOS cell unit (52), and the MOS cell unit (50) in the second N-type epitaxial layer (5) are adjusted according to application requirements, wherein there is at least one MOS cell unit (50), and they may all be MOS cell units (50).

3. The multi-trench super-junction IGBT device according to claim 1, characterized in that resistivity of the second N-type epitaxial layer (5) is larger than that of the first N-type epitaxial layer (3), and the resistivity of the second N-type epitaxial layer (5) is in a range of 4-40 Ω·cm.

4. The multi-trench super-junction IGBT device according to claim 1, characterized in that a thickness of the second N-type epitaxial layer (5) is in a range of 4-40 μm.

5. The multi-trench super-junction IGBT device according to claim 1, characterized in that the P-column (4) is formed by deep trench etching and silicon backfilling process or multiple epitaxy and ion implantation and formed by high-temperature annealing

6. The multi-trench super-junction IGBT device according to claim 1, characterized in that the P-column (4) is not in contact with the P-type body region (9) and the trench (6).

7. The multi-trench super-junction IGBT device according to claim 1, characterized in that an upper layer of the metallization collector (1) is epitaxially formed with a field stop layer having a lower resistivity than the resistivity of the first N-type epitaxial layer (3), the field stop layer having a thickness in a range of 10-40 μm.

8. The multi-trench super-junction IGBT device according to claim 7, characterized in that the multi-trench super junction IGBT device is a P-channel multi-trench super-junction IGBT device.

9. The multi-trench super-junction IGBT device according to claim 6, characterized in that the multi-trench super junction IGBT device is a P-channel multi-trench super-junction IGBT device.

10. The multi-trench super-junction IGBT device according to claim 5, characterized in that the multi-trench super junction IGBT device is a P-channel multi-trench super-junction IGBT device.

11. The multi-trench super junction IGBT device according to claim 4, characterized in that the multi-trench super junction IGBT device is a P-channel multi-trench super-junction IGBT device.

12. The multi-trench super-junction IGBT device according to claim 3, characterized in that the multi-trench super junction IGBT device is a P-channel multi-trench super-junction IGBT device.

13. The multi-trench super-junction IGBT device according to claim 2, characterized in that the multi-trench super junction IGBT device is a P-channel multi-trench super-junction IGBT device.

14. The multi-trench super-junction IGBT device according to claim 1, characterized in that the multi-trench super junction IGBT device is a P-channel multi-trench super-junction IGBT device.

15. The multi-trench super-junction IGBT device according to claim 6, characterized in that a semiconductor material in the IGBT device is bulk silicon, silicon carbide, gallium arsenide, indium phosphide or silicon germanium.

16. The multi-trench super-junction IGBT device according to claim 5, characterized in that a semiconductor material in the IGBT device is bulk silicon, silicon carbide, gallium arsenide, indium phosphide or silicon germanium.

17. The multi-trench super-junction IGBT device according to claim 4, characterized in that a semiconductor material in the IGBT device is bulk silicon, silicon carbide, gallium arsenide, indium phosphide or silicon germanium.

18. The multi-trench super-junction IGBT device according to claim 3, characterized in that a semiconductor material in the IGBT device is bulk silicon, silicon carbide, gallium arsenide, indium phosphide or silicon germanium.

19. The multi-trench super-junction IGBT device according to claim 2, characterized in that a semiconductor material in the IGBT device is bulk silicon, silicon carbide, gallium arsenide, indium phosphide or silicon germanium.

20. The multi-trench super-junction IGBT device according to claim 1, characterized in that a semiconductor material in the IGBT device is bulk silicon, silicon carbide, gallium arsenide, indium phosphide or silicon germanium.
